(19) United States
(12) Patent Application Publication
(10) Pub. No.: US 2004/0048428 A1
(43) Pub. Date: Mar. 11, 2004

(54) Semiconductor device and method of manufacturing the same

(75) Inventor: Masahiro Tanomura, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/640,319

(22) Filed: Aug. 14, 2003

(30) Foreign Application Priority Data
Aug. 15, 2002 (JP) 2002-236757

(51) Int. Cl. H01L 21/8238

(52) U.S. Cl. 438/199

(57) ABSTRACT

A semiconductor device having a bipolar transistor includes a semiconductor substrate, a collector well, a base layer, an emitter layer, a heavily doped layer. An STI structure is formed in the surface of the semiconductor substrate to have a plurality of insulating films. The collector well is formed in the semiconductor substrate in a depth direction to have a first region from the surface of the semiconductor substrate between two of the plurality of insulating films as first and second insulating films and a second region extending from the first region under the plurality of insulating films. The base layer is formed in a surface of the collector well, and the emitter layer is formed in a surface of the base layer. The heavily doped layer is formed under at least one of the plurality of insulating films within the second region of the collector well. A base electrode, an emitter electrode and a collector electrode are connected with the base layer, the emitter layer, and the heavily doped layer, respectively. A carrier density of an upper portion of the heavily doped layer is equal to or higher than that of the collector well in a portion corresponding to the upper portion in the depth direction.

### BACKGROUND OF THE INVENTION

1. Field of the Invention

The present invention relates to a semiconductor device and a method for manufacturing the same. More particularly, the present invention relates to a bipolar transistor with an STI (Shallow Trench Isolation) structure and a method for manufacturing the same.

2. Description of the Related Art

In a bipolar transistor, to reduce collector resistance is important to improve characteristics. More specifically, as a result of the reduction of collector resistance, transition frequency (fT)×maximum oscillation frequency (fmax) as an important indicator of high frequency characteristic is improved. Furthermore, in terms of the circuit operation, the reduction of collector resistance brings about positive effects such as improvement of switching speed, efficiency increase and distortion reduction of an amplifier.

In general, the collector resistance can be reduced by increasing an impurity concentration at the time of forming a collector well. In this case, however, the impurity concentration near a collector-base boundary becomes high with the reduction of collector resistance, which causes the increase of a collector-base capacitance and the reduction of a breakdown voltage.

The increase of collector-base capacitance causes not only the reduction of transition frequency (fT)×maximum oscillation frequency (fmax) but also instability of a circuit operation. As a result, oscillation is easy to be generated and the efficiency reduction and distortion increase of an amplifier is brought about. Also, the reduction of breakdown voltage restricts the circuit operation. For these reasons, the method of increasing impurity concentration is not sufficient to reduce the collector resistance.

FIG. 1 shows a conventional bipolar transistor which is disclosed in Japanese Laid Open Patent Application (JP-p-Showa-61-007664). In this conventional bipolar transistor, a heavily doped collector buried layer 103a is formed in a semiconductor substrate 101, and a lightly doped collector epitaxial layer 103b and a heavily doped layer 103c are formed on predetermined areas of the heavily doped collector buried layer 103a. A base layer 104 is formed on the lightly doped collector epitaxial layer 103b, and an emitter diffusion region 105 is formed in the surface of the base layer 104. An emitter polysilicon electrode 108 is formed on the emitter diffusion region 105, and is connected to an emitter wiring 110 through a tungsten (W) plug 109 provided within an insulating film 107. A base electrode 106a is formed on the base layer 104. A tungsten plug 109 connected to the base electrode 106a penetrates the insulating film 107 to reach a base wiring 111. A collector electrode 106b is formed on the heavily doped layer 103c. A tungsten plug 109 connected to the collector electrode 106b penetrates the insulating film 107 to reach a collector wiring 112.

In this conventional bipolar transistor, the heavily doped collector buried layer 103a is formed in the semiconductor substrate 101 apart from the base layer 104, and the doping concentration near a collector-base boundary is low. Thus, collector-base capacitance can be kept low, and breakdown voltage can be kept high.

However, this conventional bipolar transistor requires a process of forming the lightly doped collector epitaxial layer 103b and is high in manufacturing cost, compared with a bipolar transistor in which the collector is formed by using only the ion implantation.

In a BiCMOS (Bipolar Complementary Metal Oxide Semiconductor) process, a bipolar transistor and a CMOS (Complementary Metal Oxide Semiconductor) transistor are formed on the same substrate. In case of applying the conventional method of manufacturing a bipolar transistor to the BiCMOS process, new problems occur in forming fine patterns because a CMOS needs to be formed by using the semiconductor substrate in which the lightly doped collector epitaxial layer 103b is formed. When there is no process of forming a collector buried layer and a collector epitaxial layer in a bipolar transistor, not only manufacturing cost is suppressed but also the bipolar transistor can be applied to a BiCMOS transistor relatively easily.

FIG. 2 shows a conventional example of a bipolar transistor without a collector buried layer and a collector epitaxial layer. In this conventional example, an STI (Shallow Trench Isolation) structure is formed on a semiconductor substrate 101 to form isolation insulating films 102. A collector well 103 is formed in the semiconductor substrate 101. A base layer 104 is formed on the collector well 103, and an emitter diffusion region 105 is formed in the surface of the base layer 104. An emitter polysilicon electrode 108 is formed on the emitter diffusion region 105, and is connected to an emitter wiring 110 through a tungsten plug 109 provided within an insulating film 107. A base electrode 106a is formed on the base layer 104, and a tungsten plug 109 connected to the base electrode 106a penetrates the insulating film 107 to reach a base wiring 111. A collector electrode 106b is formed between the insulating films 102 of the STI structure in the bottom of the insulating films 102. A collector trench 113 is formed on the collector electrode 106b so as to penetrate the isolation insulating film. A collector tungsten plug 114 connected to the collector electrode 106b penetrates the isolation insulating film 102 and the insulating film 107 to reach a collector wiring 112.

This bipolar transistor has no collector buried layer and collector epitaxial layer. Moreover, the collector resistance in a vertical direction is reduced due to the collector tungsten plug 114.

FIG. 3 shows another conventional example of a bipolar transistor with an STI structure. In this bipolar transistor, vertical collector resistance is reduced due to a vertical heavily doped layer 115 provided under the collector electrode 106b.

In conjunction with the above description, a conventional bipolar transistor is disclosed in Japanese Laid Open Patent Application (JP-P-Heisei-11-312687), in which a DTI (Deep Trench Isolation) structure is formed as well as an STI structure. The bipolar transistor is formed on a lightly doped n-type semiconductor substrate, and includes a heavily doped collector conducting layer in a collector region which electrically connects a device operation region and a collector electrode.

Also, another bipolar transistor with STI and DTI structures is disclosed in Japanese Laid Open Patent Application (JP-P2001-35858A), which is a hetero bipolar transistor contrived to reduce base resistance.

Also, another conventional bipolar transistor with a low collector-base capacitance is disclosed in Japanese Laid Open Patent Application (JP-P2001-338931A), in which a silicon-germanium layer is formed between a base layer and a collector layer. The layers are formed through epitaxial growth. The silicon-germanium layer has the same conductive type as the collector layer near the base layer, and the same conductive type as the base layer in peripheral part.

### SUMMARY OF THE INVENTION

Therefore, an object of the present invention is to provide a semiconductor device having a bipolar transistor in which collector resistance of the bipolar transistor is substantially reduced, and a method for manufacturing the same.

Another object of the present invention is to provide a semiconductor device having a bipolar transistor, in which increase of a collector-base capacitance and collector-substrate capacitance and characteristic deterioration such as reduction of breakdown voltage and so on are not caused in spite of the reduction of collector resistance, and a method for manufacturing the same.

Still another object of the present invention is to provide a bipolar transistor which can be fabricated in a BiCMOS process, and a method for manufacturing the same.

In an aspect of the present invention, a semiconductor device having a bipolar transistor includes a semiconductor substrate, a collector well, a base layer, an emitter layer, a heavily doped layer. An STI structure is formed in the surface of the semiconductor substrate to have a plurality of insulating films. The collector well is formed in the semiconductor substrate in a depth direction to have a first region from the surface of the semiconductor substrate between two of the plurality of insulating films as first and second insulating films and a second region extending from the first region under the plurality of insulating films. The base layer is formed in a surface of the collector well, and the emitter layer is formed in a surface of the base layer. The heavily doped layer is formed under at least one of the plurality of insulating films within the second region of the collector well. A base electrode, an emitter electrode and a collector electrode are connected with the base layer, the emitter layer, and the heavily doped layer, respectively. A carrier density of an upper portion of the heavily doped layer is equal to or higher than that of the collector well in a portion corresponding to the upper portion in the depth direction.

Here, the heavily doped layer may be formed under the second insulating film in the collector well. In this case, the heavily doped layer may be formed under the second insulating film in the collector well apart from a base side edge of the second insulating film by a distance equal to or more than 0.1 μm.

Also, the heavily doped layer may be formed under the second insulating film in the collector well to extend to under one of the plurality of insulating films as a third insulating film which is provided on a side opposite to the base layer with respect to the second insulating film. In this case, the heavily doped layer may be formed under the second insulating film in the collector well apart from a base side edge of the second insulating film by a distance equal to or more than 0.1 μm. Also, the heavily doped layer may have a first upwardly extending portion extending to the surface of the semiconductor substrate between the second insulating film and the third insulating film, and the collector electrode may be provided on the surface of the semiconductor substrate to contact with the first upwardly extending portion. Alternatively, the semiconductor device may further include a first contact plug extending into the depth direction in the semiconductor substrate between the second insulating film and the third insulating film. The collector electrode is formed in the collector well to contact with the heavily doped layer and the first contact plug.

Also, the heavily doped layer may be formed under the first and second insulating films in the collector well to surround a region below the base layer in the collector well. In this case, the heavily doped layer may be formed under the first insulating film in the collector well apart from a base side edge of the first insulating film by a distance equal to or more than 0.1 μm, and under the second insulating film in the collector well apart from a base side edge of the second insulating film by a distance equal to or more than 0.1 μm.

Also, the heavily doped layer may be further formed under the first insulating film in the collector well to extend to under one of the plurality of insulating films as a fourth insulating film which is provided on a side opposite to the base layer with respect to the first insulating film. In this case, the heavily doped layer may be formed under the first insulating film in the collector well apart from a base side edge of the first insulating film by a distance equal to or more than 0.1 μm, and under the second insulating film in the collector well apart from a base side edge of the second insulating film by a distance equal to or more than 0.1 μm. Also, the heavily doped layer is desirably formed to surround a region below the base layer in the collector well. In this case, the heavily doped layer may have a second upwardly extending portion extending to the surface of the semiconductor substrate between the first insulating film and the fourth insulating film, and another collector electrode may be provided on the surface of the semiconductor substrate to contact with the second upwardly extending portion. Also, the semiconductor device may further includes a second contact plug extending into the depth direction in the semiconductor substrate between the first insulating film and the fourth insulating film.

Also, the collector well has a carrier density profile in which the carrier density is lower under the base layer, increases to have a peak carrier density in a middle portion of the collector well in the depth direction, and decreases from the peak carrier density into the depth direction from the middle portion.

In another aspect of the present invention, a method of manufacturing a semiconductor device includes (a) forming an STI (Shallow Trench Isolation) structure with a plurality of insulating films in a surface of a semiconductor substrate; (b) forming a collector well in the semiconductor substrate in a depth direction to have a first region from a surface of the semiconductor substrate between two of the plurality of insulating films as first and second insulating films and a second region extending from the first region under the plurality of insulating films; (c) forming a base layer to be in contact with the collector well; and (d) forming a heavily doped layer under at least one of the plurality of insulating films within the second region of the collector well such that a carrier density of an upper portion of the heavily doped layer is equal to or higher than that of the collector well in a portion corresponding to the upper portion.

Here, the (d) forming may be achieved by (e) forming a vertical heavily doped layer between the second insulating film and one of the plurality of insulating films as a third insulating film which is provided on a side opposite to the base layer with respect to the second insulating film; and by (f) forming a horizontal heavily doped layer under at least one of the plurality of insulating films within the second region of the collector well such that the horizontal heavily doped layer is connected to the vertical heavily doped layer. The (f) forming may be carried out such that the horizontal heavily doped layer extends around a region below the base layer in the collector well. Also, the (f) forming may be carried out such that the horizontal heavily doped layer forms a ring shape surrounding a region below the base layer in the collector well. Also, the (f) forming may be carried out such that a horizontal distance between the base layer and a base side edge of the horizontal heavily doped layer is equal to or more than 0.1 μm.

Also, the method may be achieved by (g) forming a collector electrode in the collector well below a region between the second insulating film and one of the plurality of insulating films as a third insulating film which is provided on a side opposite to the base layer with respect to the second insulating film; and by (h) forming a contact plug on the collector electrode between the second insulating film and the third insulating film. The heavily doped layer is connected to the collector electrode and horizontally extends to under at least one of the plurality of insulating films. In this case, the (d) forming may be carried out such that the heavily doped layer extends around a region below the base layer in the collector well. Also, the (d) forming may be carried out such that the heavily doped layer forms a ring shape surrounding a region below the base layer in the collector well. In addition, the (d) forming may be carried out such that a horizontal distance between the base layer and a base side edge of the heavily doped layer is equal to or more than 0.1 μm.

Thus, it is possible according to the present invention not only to apply the semiconductor device to a BiCMOS (Bipolar Complementary Metal Oxide Semiconductor) transistor without difficulty but also to reduce vertical collector resistance and horizontal collector resistance substantially without increase of collector-base capacitance and collector-substrate capacitance and reduction of collector-base breakdown voltage, resulting in high transition frequency (fT) and high maximum oscillation frequency (fmax).

### BRIEF DESCRIPTION OF THE DRAWINGS

FIG. 1 is a cross sectional view schematically showing a structure of a conventional bipolar transistor;

FIG. 2 is a cross sectional view schematically showing a structure of another conventional bipolar transistor;

FIG. 3 is a cross sectional view schematically showing a structure of another conventional bipolar transistor;

FIG. 4 is a cross sectional view schematically showing a structure of a bipolar transistor according to a first embodiment of the present invention;

FIG. 5 is a plan view schematically showing a positional relationship between a collector well, a base layer and a heavily doped layer in the bipolar transistor according to the first embodiment of the present invention;

FIG. 6 shows carrier densities in the collector well and the heavily doped layer as a function of depth from a collector-base boundary in the bipolar transistor according to the first embodiment of the present invention;

FIG. 7A is a cross sectional view schematically showing a method for manufacturing the bipolar transistor according to the first embodiment of the present invention;

FIG. 7B is a cross sectional view schematically showing a method for manufacturing the bipolar transistor according to the first embodiment of the present invention;

FIG. 8 is a cross sectional view schematically showing another structure of the bipolar transistor according to the first embodiment of the present invention;

FIG. 9 is a cross sectional view schematically showing still another structure of the bipolar transistor according to the first embodiment of the present invention;

FIG. 10 is a plan view schematically showing a positional relationship between a collector well, a base layer and a heavily doped layer of the bipolar transistor in FIG. 9;

FIG. 11 is a cross sectional view schematically showing a structure of a bipolar transistor according to a second embodiment of the present invention;

FIG. 12 is a top view schematically showing a positional relationship between a collector well, a base layer and a heavily doped layer of the bipolar transistor according to the second embodiment of the present invention;

FIG. 13 shows collector resistance and collector-base leak current as a function of a horizontal distance (Lc) between the base layer and a base side edge of the horizontal heavily doped layer according to the second embodiment of the present invention;

FIG. 14 is a cross sectional view schematically showing a structure of a bipolar transistor according to a third embodiment of the present invention; and

FIG. 15 is a plan view schematically showing a positional relationship between a collector well, a base layer, a heavily doped layer and a collector tungsten plug of the bipolar transistor according to the third embodiment of the present invention.

### DESCRIPTION OF THE PREFERRED EMBODIMENTS

A bipolar transistor of the present invention will be described below in detail with reference to the attached drawings.

[First Embodiment]

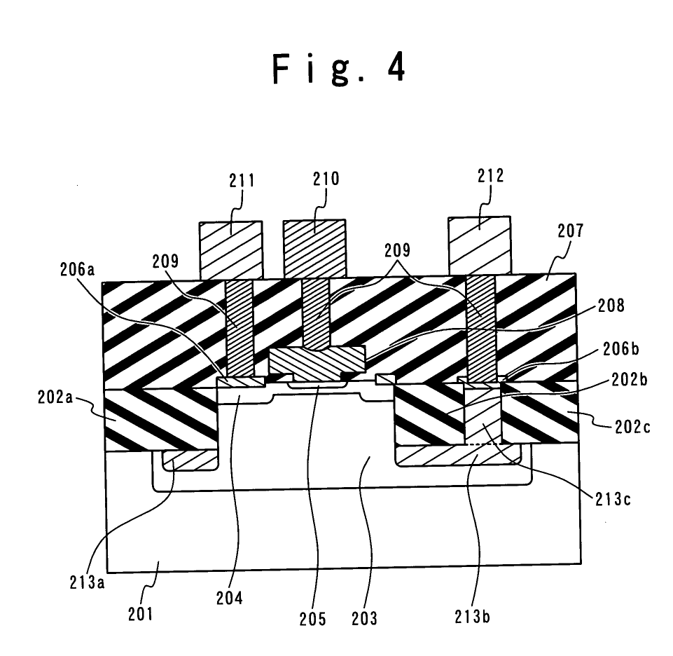

FIG. 4 is a cross sectional view schematically showing the structure of a semiconductor device according to a first embodiment of the present invention. Referring to FIG. 4, an STI (Shallow Trench Isolation) structure is formed on a p-type silicon substrate 201 to have a plurality of isolation insulating films 202a, 202b and 202c. A collector well 203 as an n-type conductive layer is formed in the p-type silicon substrate 201 through an ion implantation process. A base layer 204 as a p-type conductive layer is formed in the collector well 203 between the isolation insulating films 202a and 202b, and an emitter diffusion region 205 is formed in the surface of the base layer 204.

An emitter polysilicon electrode 208 is formed on the emitter diffusion region 205. A tungsten (W) plug 209 connected to the emitter polysilicon electrode 208 penetrates an insulating film 207 to reach an emitter wiring 210 formed on the insulating film 207. A silicide base electrode 206a is formed on the base layer 204. A tungsten plug 209 connected to the silicide base electrode 206a penetrates the insulating film 207 to reach a base wiring 211 formed on the insulating film 207.

A heavily doped layer 213 (213a, 213b and 213c) is formed in the collector well 203, in which n-type dopant is implanted through an ion implantation process. The heavily doped layer is located in a region other than a region below the base layer under at least one of the plurality of STI structures. In this example, the heavily doped layer is formed under the insulating films 202a, 202b and 202c. The heavily doped layer can be separated into two parts, a horizontal part and a vertical part which are connected with each other. The vertical heavily doped layer 213c is formed between the isolation insulating films 202b and 202c. A silicide collector electrode 206b is formed on the vertical heavily doped layer 213c. A tungsten plug 209 connected to the silicide collector electrode 206b penetrates the insulating film 207 to reach a collector wiring 212 formed on the insulating film 207. The horizontal heavily doped layer 213b is connected to the vertical heavily doped layer 213c and horizontally extends under the isolation insulating films 202b and 202c. Moreover, the horizontal heavily doped layer 213b can extend horizontally around the region under the base layer 204 within the collector well 203. Therefore, the horizontal heavily doped layer 213a can be formed under the isolation insulating film 202a, which is electrically connected to the horizontal heavily doped layer 213b.

The horizontal heavily doped layer 213a has a smaller area and less thickness than those of the collector well 203 under the isolation insulating film 202a. The horizontal heavily doped layer 213b has a smaller area and less thickness than those of the collector well 203 under the vertical heavily doped layer 213c and the isolation insulating films 202b and 202c. That is to say, the heavily doped layer 213 (213a, 213b and 213c) is formed within the collector well 203, but in a region other than the region below the base layer 204. Furthermore, the heavily doped layer is not contiguous with the p-type silicon substrate 201.

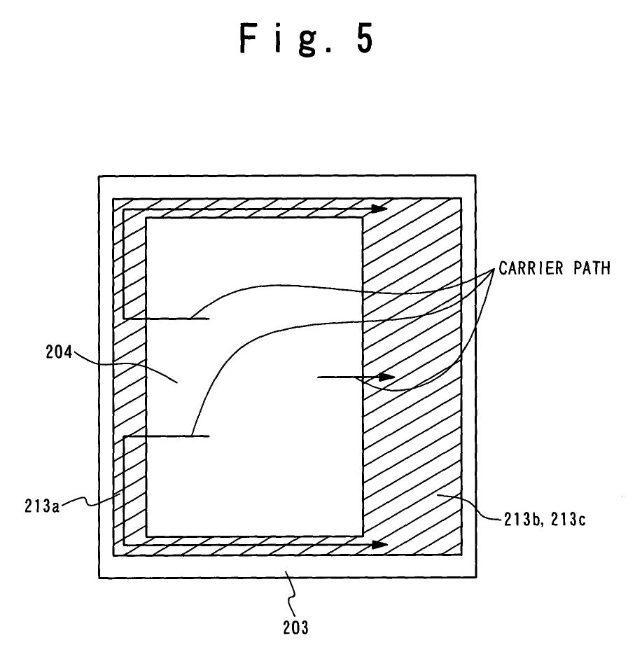

FIG. 5 is a plan view showing a positional relationship between the collector well 203, the base layer 204 and the heavily doped layer 213 (213a, 213b and 213c). The horizontal heavily doped layer 213b can extend around the region below the base layer 204. In case of FIG. 5, the area of the horizontal heavily doped layer 213 has a “ring shape” to surround the region of the base layer 204. The horizontal heavily doped layer 213a is connected with the horizontal heavily doped layer 213b. In other words, the heavily doped layer is formed within the collector well 203 and in the region other than the region below the base layer 204.

Arrows in FIG. 5 indicate carrier paths in the collector well 203 and the heavily doped layer. The current flows from the base layer 204 not only directly to the horizontal heavily doped layer 213b but also through the horizontal heavily doped layer 213a to the horizontal heavily doped layer 213b.

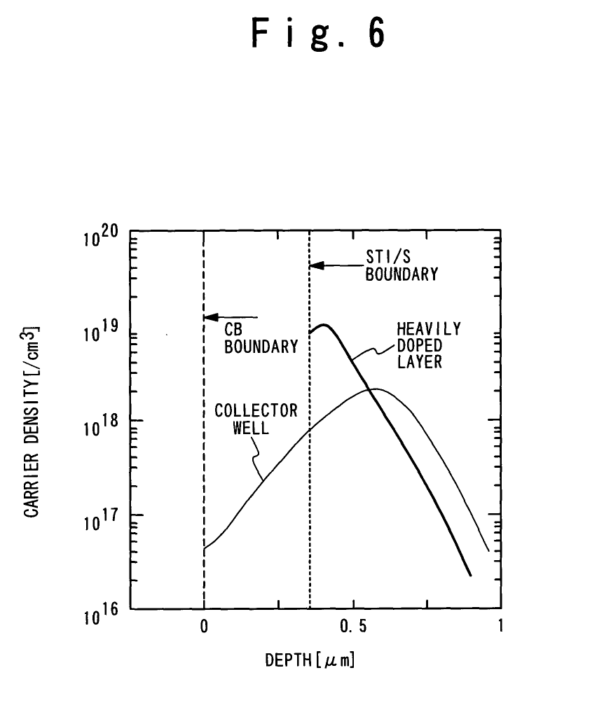

FIG. 6 shows carrier density (impurity density) in the collector well 203 and the heavily doped layer (213a and 213b) as a function of depth from a collector-base (CB) boundary. A vertical short dotted line indicates the boundary between the STI structure and the semiconductor substrate (STI/S), i.e., the boundary between the horizontal heavily doped layer and the isolation insulating film. A thin curve and a thick curve in FIG. 6 indicate profiles of carrier density in the collector well 203 and the heavily doped layer (213a and 213b), respectively. At the STI/S boundary, the carrier density in the heavily doped layer is higher than that in the collector well 203, and decreases with increasing depth. Also, the carrier density in the collector well 203 is low near the CB boundary and near the p-type silicon substrate 201.

Generally, in a bipolar transistor where a collector well is formed by ion implantation, there are the following relationships between the carrier density in the collector well and the collector resistance, collector-base capacitance, collector-base breakdown voltage and collector-substrate capacitance:

(1) collector resistance˜1/(carrier density);

(2) collector-base capacitance˜(carrier density)^{0.5};

(3) collector-base breakdown voltage˜1/(carrier density)^{0.5}; and

(4) collector-substrate capacitance˜(carrier density)^{0.5}.

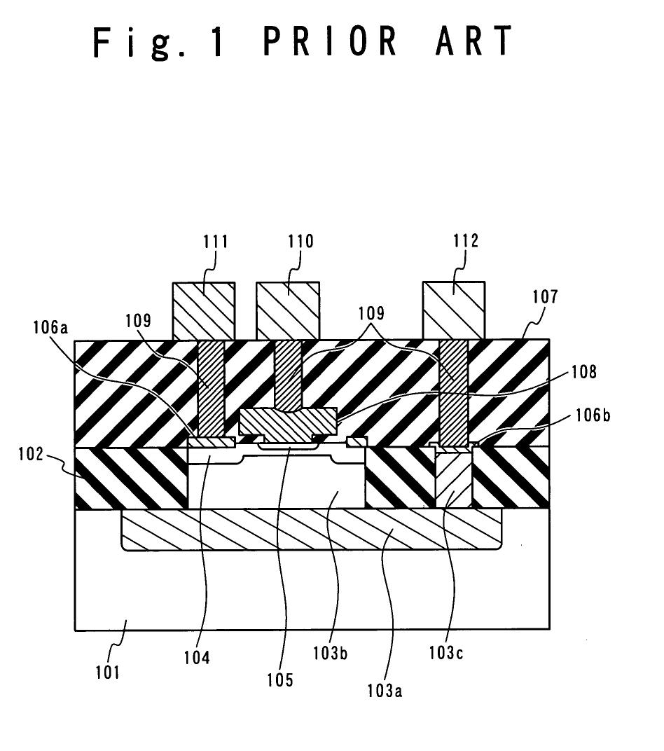

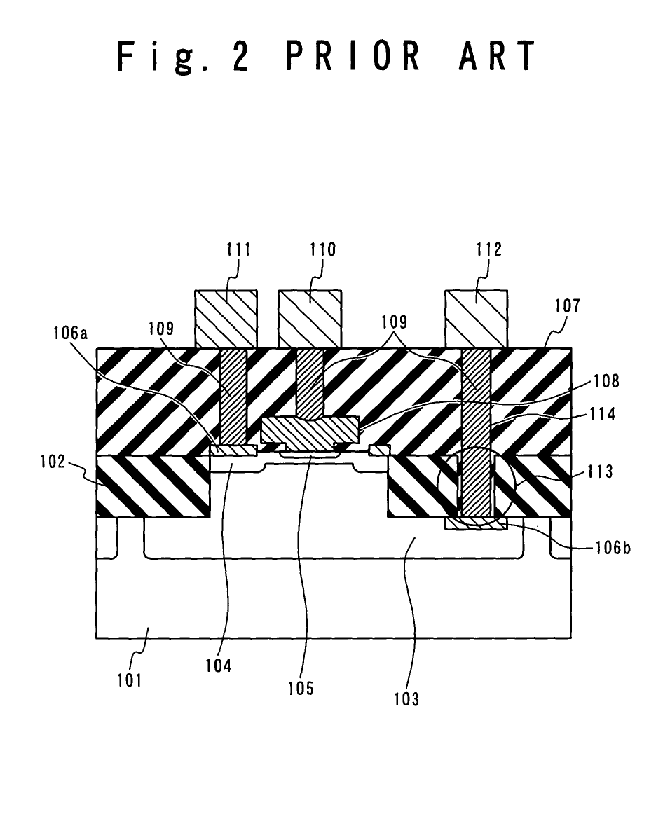

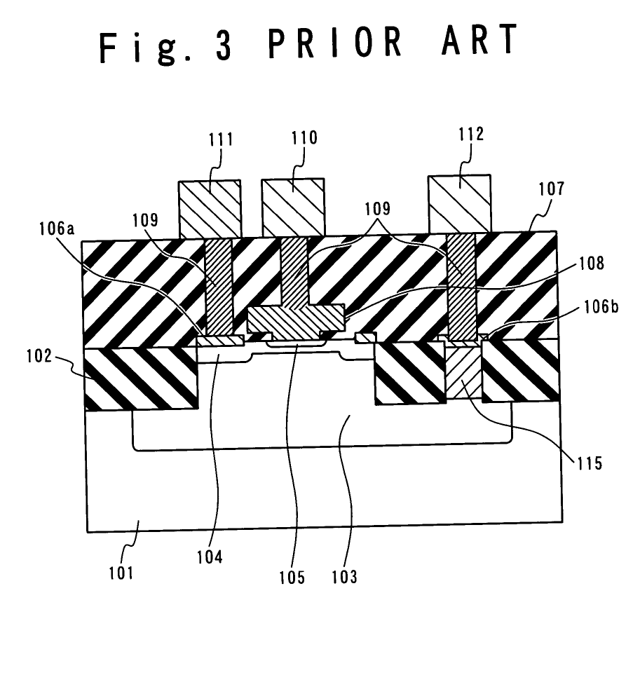

As described above, in the semiconductor device according to the first embodiment of the present invention, collector resistance can be reduced without a heavily doped collector buried layer and a lightly doped collector epitaxial layer, unlike the conventional bipolar transistor shown in FIG. 1, by employing the horizontal and vertical heavily doped layers 213 (213a, 213b and 213c) shown in FIG. 4 (see the above relationship (1)). This allows the bipolar transistor according to the present invention to be applied easily to a BiCMOS transistor.

Moreover, the heavily doped layer extends not only vertically but also horizontally, i.e., includes not only the vertical heavily doped layer 213c between the isolation insulating films 202b and 202c but also the horizontal heavily doped layers 213a and 213b under the isolation insulating films 202a, 202b and 202c, as shown in FIG. 4. This allows horizontal collector resistance to be reduced as well as vertical collector resistance.

Furthermore, as shown in FIG. 5, the current flows from the base layer 204 not only directly to the horizontal heavily doped layer 213b but also through the horizontal heavily doped layer 213a to the horizontal heavily doped layer 213b. Thus, it is possible to reduce collector resistance further.

The above relationships (2) and (3) imply that there is a “trade-off” relation that the collector-base capacitance becomes large and the collector-base breakdown voltage becomes low when the carrier density in the collector well is increased to reduce the collector resistance. According to the present invention, however, the horizontal heavily doped layers 213a and 213b are formed under the isolation insulating films 202a, 202b and 202c, i.e., under the region other than the base layer 204, as shown in FIGS. 4 and 5. The carrier density is low near the collector-base boundary as shown in FIG. 6.

Therefore, the increase of collector-base capacitance and the reduction of collector-base breakdown voltage are not caused.

Furthermore, the horizontal heavily doped layers 213a and 213b have less thickness than that of the collector well 203, are formed within the collector well 203, and are not contiguous with the p-type silicon substrate 201 as shown in FIGS. 4 and 5.

Also, the carrier density in the collector well 203 and the horizontal heavily doped layers 213a and 213b tends to decrease with increasing depth from the STI/S boundary, and becomes substantially low near the bottom of the collector well 203, as shown in FIG. 6. Therefore, the increase of collector-substrate capacitance as implied by the above relationship (4) is not caused with regard to capacitance between the p-type silicon substrate 201 and the collector well 203 and the heavily doped layer.

Thus, according to the present invention, it is possible to reduce the vertical collector resistance and the horizontal collector resistance substantially without increase of collector-base capacitance and collector-substrate capacitance and the reduction of collector-base breakdown voltage, resulting in high transition frequency (fT) and high maximum oscillation frequency (fmax). Also, the bipolar transistor of the present invention can be applied to a BiCMOS without difficulty.

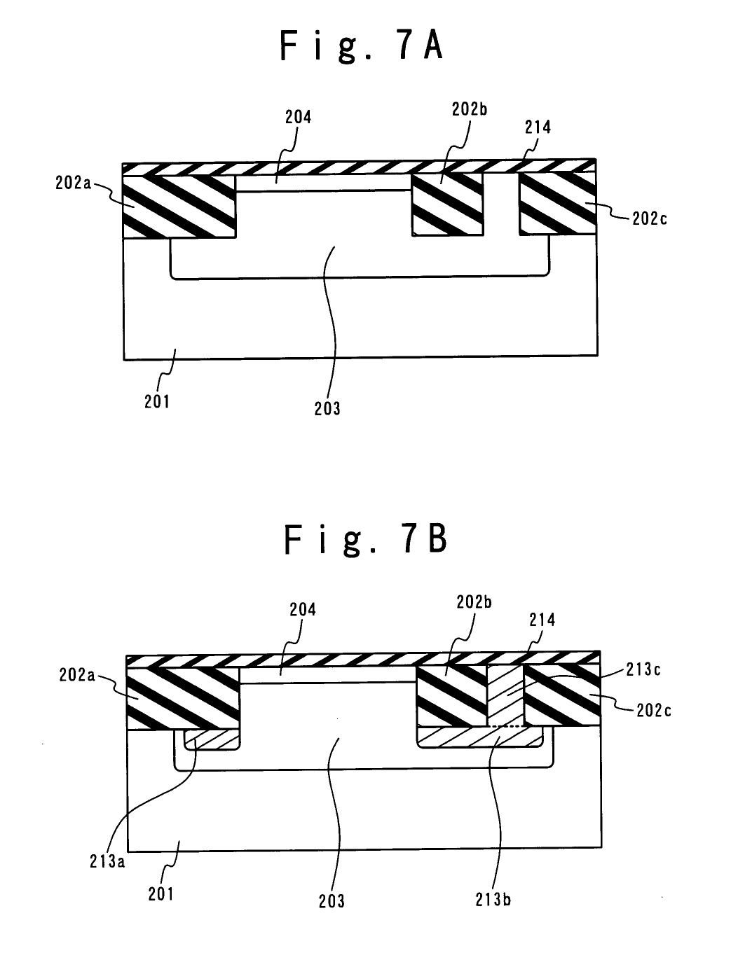

Next, a method for manufacturing the bipolar transistor according to the present embodiment will be described with reference to FIGS. 7A and 7B.

As shown in FIG. 7A, an STI structure is formed on the p-type silicon substrate 201 to have the plurality of isolation insulating films 202a, 202b and 202c. An insulating film 214 is formed on the p-type silicon substrate 201 and the isolation insulating films 202a, 202b and 202c. The collector well 203 as an n-type conductive layer and the base layer 204 as a p-type conductive layer are formed through ion implantation processes. Here, acceleration voltage and a dose amount in the ion implantation processes are controlled such that impurity density in the collector well 203 is low near the collector—base boundary and near the p-type silicon substrate 201 as shown in FIG. 6.

After that, as shown in FIG. 7B, the horizontal heavily doped layers 213a and 213b and the vertical heavily doped layer 213c are formed under the isolation insulating films 202a, 202b and 202c and between the isolation insulating films 202b and 202c, respectively, through an ion implantation process. The heavily doped layers are formed under the region other than the region below the base layer 204. Here, an acceleration voltage and a dose amount in the ion implantation process are controlled such that the impurity density in the horizontal heavily doped layers 213a and 213b is higher than that in the collector well 203 near the STI/S boundary, and decreases with increasing depth, as shown in FIG. 6.

After that, the emitter diffusion layer 205, the emitter polysilicon electrode 208, the silicide base electrode 206a, the silicide collector electrode 206b, the insulating film 207, the tungsten plug 209, the emitter wiring 210, the base wiring 211 and the collector wiring 212 are formed (not shown). Thus, the structure of the bipolar transistor shown in FIG. 4 is attained. It should be noted that the method mentioned above is one example, and other doping methods are possible by which the horizontal and vertical heavily doped layers 213a, 213b and 213c are formed as in FIG. 4 and FIG. 6.

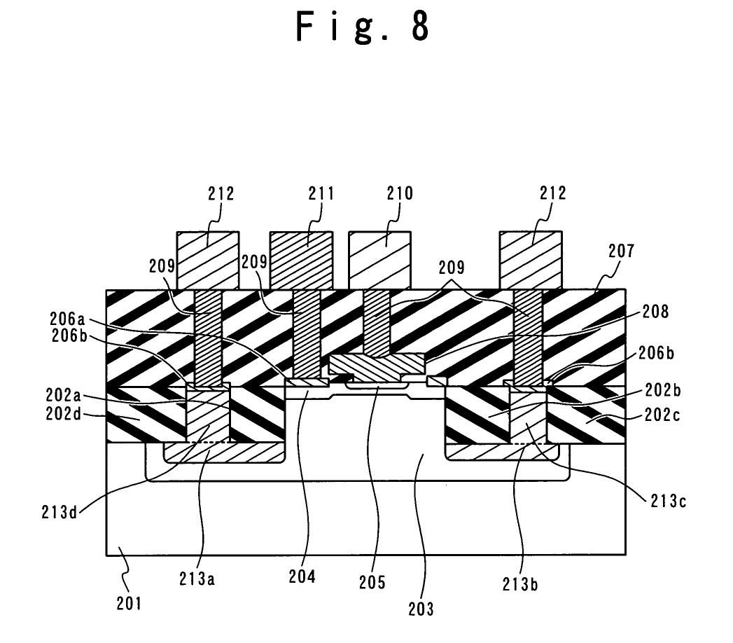

FIG. 8 shows a modified example of the bipolar transistor according to the resent embodiment. In this bipolar transistor, the collector wirings 212 are provided on both sides of a base/emitter region. In this case, the vertical heavily doped layer 213d is formed on the horizontal heavily doped layer 213a. A silicide collector electrode is formed on the vertical heavily doped layer 213d, and is connected to the additional collector wiring 212 through a tungsten plug 209.

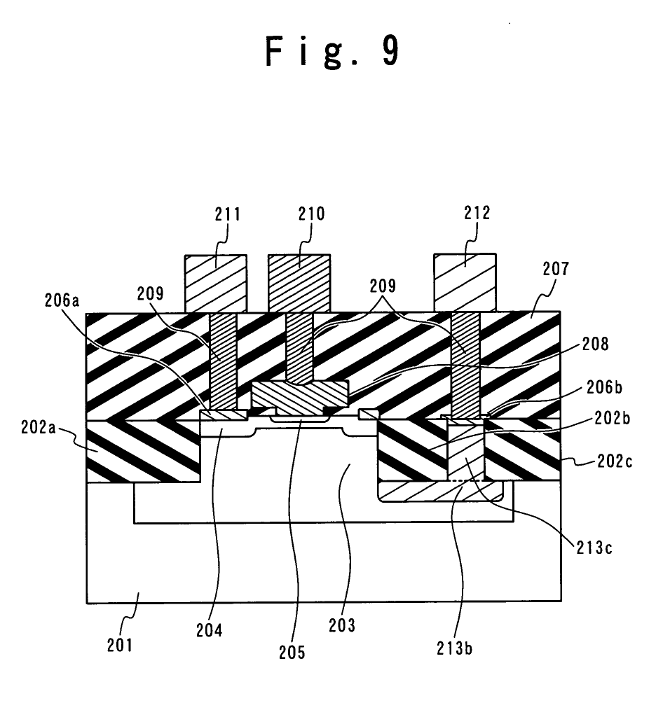

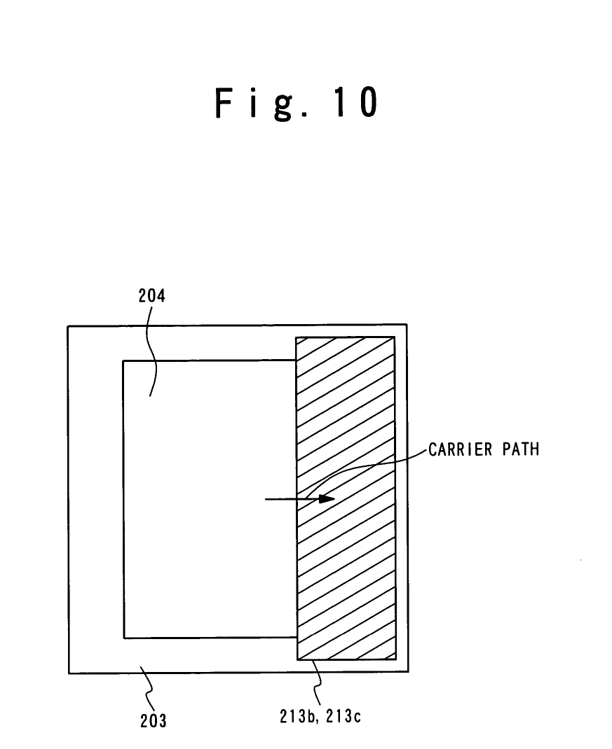

FIG. 9 shows another modified example of the bipolar transistor according to the present embodiment. In this bipolar transistor, the horizontal heavily doped layer 213a is not formed in the collector well 203. FIG. 10 is a plan view showing a positional relationship between the collector well 203, the base layer 204 and the heavily doped layer (213b and 213c). The heavily doped layer is formed within the collector well 203 and in the region other than the region below the base layer 204. Since the structure of the heavily doped layer becomes simple, manufacturing the bipolar transistor becomes easier.

[Second Embodiment]

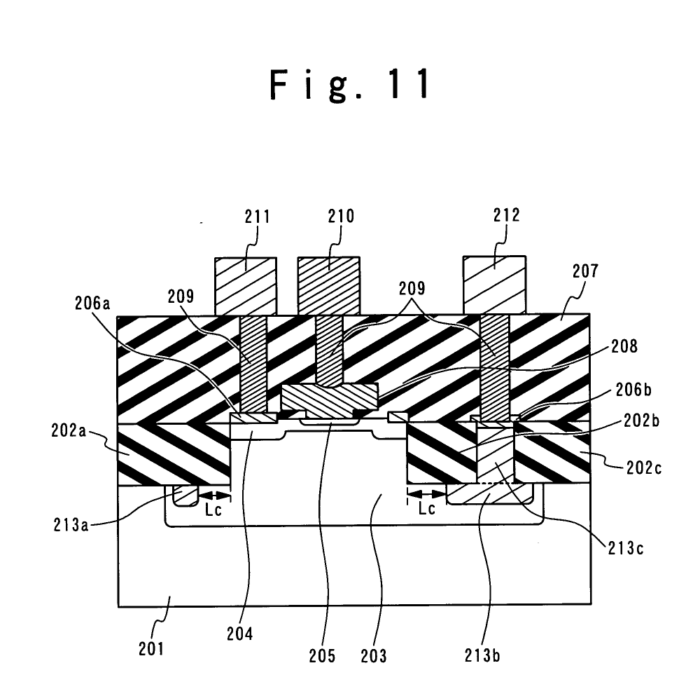

FIG. 11 is a cross sectional view schematically showing the structure of a bipolar transistor of a semiconductor device according to the second embodiment of the present invention. The structure of the bipolar transistor of the semiconductor device in the second embodiment is the same as that in the first embodiment, except for the horizontal heavily doped layers 213a and 213b. Therefore, the detailed description of the structure is omitted.

In FIG. 4, the horizontal heavily doped layers 213a and 213b extend up to the base side edges of the isolation insulating films 202a and 202b, respectively. In the second embodiment of the present invention, however, the horizontal heavily doped layers 213a and 213b are shortened by the length of Lc horizontally, as shown in FIG. 11. That is to say, Lc is the length from the base side edge of the isolation insulating film 202a (202b) to the inner edge of the horizontal heavily doped layer 213a (213b). In other words, Lc is a horizontal distance between the base layer 204 and the base side edge of the horizontal heavily doped layers 213a and 213b.

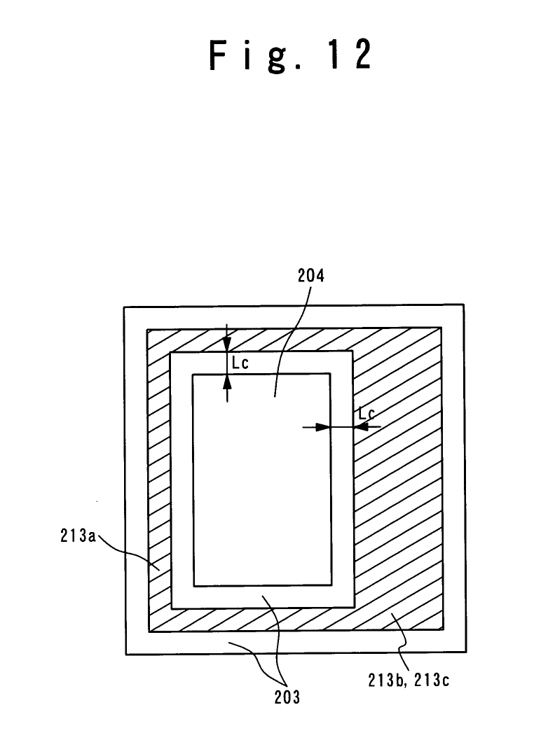

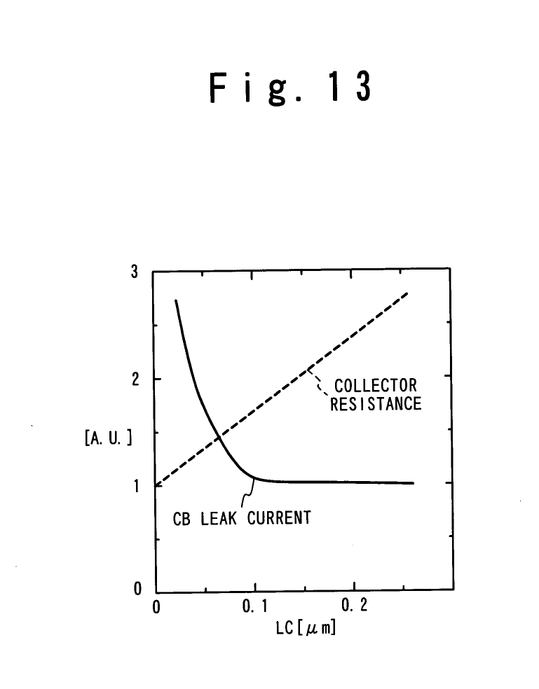

FIG. 12 is a plan view showing a positional relationship between the collector well 203, the base layer 204 and the heavily doped layer (213a, 213b and 213c). Similar to the first embodiment, the heavily doped layer is formed within the collector well 203 and in the region other than the region below the base layer 204. Moreover, as described above, the area of the heavily doped layer is detached from the area of the base layer 204, and the separation between them is Lc. In the case where Lc is 0.0 μm, i.e., the horizontal heavily doped layers 213a and 213b are formed up to the inner edge of the isolation insulating films 202a and 202b, the collector-base leak current is caused. FIG. 13 shows collector resistance and collector-base (CB) leak current as a function of Lc. A dashed line indicates the collector resistance normalized by collector resistance when Lc is 0.0 μm. A solid line indicates CB leak current normalized by CB leak current when Lc is 0.1 μm. As shown in FIG. 13, the collector resistance increases gradually as Lc becomes large. On the other hand, the collector-base leak current becomes larger with decreasing Lc, and increases remarkably when Lc becomes lower than 0.1 μm.

According to the present embodiment, the collector-base leak current can be suppressed as well as the collector resistance can be reduced as much as possible. For that purpose, it is preferable that Lc is designed to be equal to or more than 0.1 μm. Other effects in the present embodiment are the same as those in the first embodiment.

Here, it is possible in the present embodiment to remove the horizontal heavily doped layer 213a as in FIG. 9 and FIG. 10 according to the example in the first embodiment.

[Third Embodiment]

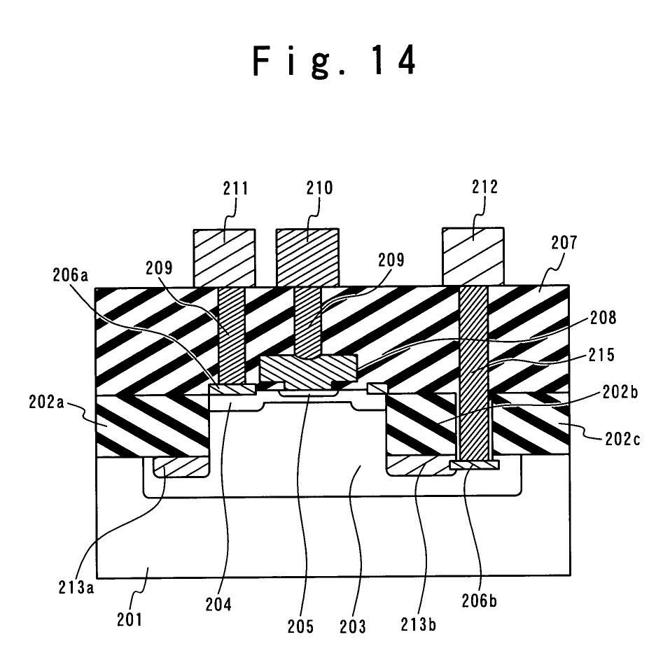

FIG. 14 is a cross sectional view schematically showing the structure of the bipolar transistor of the semiconductor device according to the third embodiment of the present invention. The structure of the semiconductor device in the third embodiment is the same as that in the first embodiment, except for the horizontal heavily doped layer 213b, the vertical heavily doped layer 213c and the collector electrode 206b. Therefore, the detailed description of the structure is omitted.

In FIG. 14, the collector electrode 206b is formed within the collector well 203 below a region between the isolation insulating films 202b and 202c, and a collector tungsten (W) plug 215 is formed on the collector electrode between the isolation insulating films 202b and 202c instead of the vertical heavily doped layer 213c. That is to say, the collector tungsten plug 215 penetrates both the insulating film 207 and the isolation insulating film. The horizontal heavily doped layer 213b is connected to the collector electrode 206b, and extends below the isolation insulating film 202b. Moreover, the horizontal heavily doped layer 213b can extend horizontally around the region below the base layer 204 within the collector well 203. Therefore, the horizontal heavily doped layer 213a can be formed under the isolation insulating film 202a, which is electrically connected to the horizontal heavily doped layer 213b.

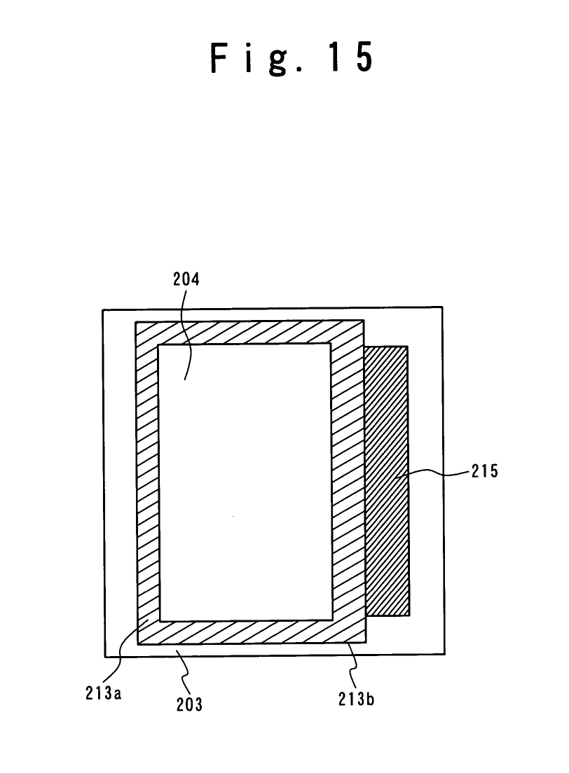

FIG. 15 is a plan view showing a positional relationship between the collector well 203, the base layer 204, the horizontal heavily doped layers 213a and 213b, and the collector tungsten plug 215. The horizontal heavily doped layer is formed within the collector well 203 and under other than the base layer 204. Moreover, as described above, the area of the horizontal heavily doped layer contacts the area of the collector tungsten plug 215. Similar to the first embodiment, the horizontal heavily doped layer 213b can extend around the region under the base layer 204. In case of FIG. 15, the area of the horizontal heavily doped layer surrounds the area of the base layer 204, to form a “ring shape”. The horizontal heavily doped layer 213a is connected with the horizontal heavily doped layer 213b.

In the bipolar transistor according to the present embodiment, the collector resistance can be further reduced not only vertically but also horizontally without increase of collector-base capacitance and collector-substrate capacitance, and the reduction of breakdown voltage.

Here, it is possible in the present embodiment to remove the horizontal heavily doped layer 213a as in FIG. 9 according to the example in the first embodiment. It is also possible to provide another tungsten plug 215 to be connected to the heavily doped layer 213a through the collector electrode 206b as in FIG. 8 according to the example in the first embodiment. It is also possible to shorten the horizontal heavily doped layers 213a and 213b as in FIG. 11 according to the second embodiment. In this case, a horizontal distance between the base layer 204 and a base side edge of the horizontal heavily doped layer is preferably equal to or more than 0.1 μm.

What is claim d is:

1. A semiconductor device having a bipolar transistor which comprises:
a semiconductor substrate in whose surface an STI structure is formed to have a plurality of insulating films;
a collector well formed in said semiconductor substrate in a depth direction to have a first region from the surface of said semiconductor substrate between two of said plurality of insulating films as first and second insulating films and a second region extending from said first region under said plurality of insulating films;
a base layer formed in a surface of said collector well;
an emitter layer formed in a surface of said base layer;
a heavily doped layer formed under at least one of said plurality of insulating films within said second region of said collector well, a base electrode connected to said base layer;
an emitter electrode connected to said emitter layer; and
a collector electrode connected with said heavily doped layer,
wherein a carrier density of an upper portion of said heavily doped layer is equal to or higher than that of said collector well in a portion corresponding to said upper portion in said depth direction.

2. The semiconductor device according to claim 1, wherein said heavily doped layer is formed under said second insulating film in said collector well.

3. The semiconductor device according to claim 2, wherein said heavily doped layer is formed under said second insulating film in said collector well apart from a base side edge of said second insulating film by a distance equal to or more than 0.1 μm.

4. The semiconductor device according to claim 1, wherein said heavily doped layer is formed under said second insulating film in said collector well to extend to under one of said plurality of insulating films as a third insulating film which is provided on a side opposite to said base layer with respect to said second insulating film.

5. The semiconductor device according to claim 4, wherein said heavily doped layer is formed under said second insulating film in said collector well apart from a base side edge of said second insulating film by a distance equal to or more than 0.1 μm.

6. The semiconductor device according to claim 4, wherein said heavily doped layer has a first upwardly extending portion extending to the surface of said semiconductor substrate between said second insulating film and said third insulating film, and
said collector electrode is provided on the surface of said semiconductor substrate to contact with said first upwardly extending portion.

7. The semiconductor device according to claim 4, further comprising:
a first contact plug extending into said depth direction in said semiconductor substrate between said second insulating film and said third insulating film,
wherein said collector electrode is formed in said collector well to contact with said heavily doped layer and said first contact plug.

8. The semiconductor device according to claim 1, wherein said heavily doped layer is formed under said first and second insulating films in said collector well to surround around a region below said base layer in said collector well.

9. The semiconductor device according to claim 8, wherein said heavily doped layer is formed under said first insulating film in said collector well apart from a base side edge of said first insulating film by a distance equal to or more than 0.1 μm, and under said second insulating film in said collector well apart from a base side edge of said second insulating film by a distance equal to or more than 0.1 μm.

10. The semiconductor device according to claim 4, wherein said heavily doped layer is further formed under said first insulating film in said collector well to extend to under one of said plurality of insulating films as a fourth insulating film which is provided on a side opposite to said base layer with respect to said first insulating film.

11. The semiconductor device according to claim 10, wherein said heavily doped layer is formed under said first insulating film in said collector well apart from a base side edge of said first insulating film by a distance equal to or more than 0.1 μm, and under said second insulating film in said collector well apart from a base side edge of said second insulating film by a distance equal to or more than 0.1 μm.

12. The semiconductor device according to claim 10, wherein said heavily doped layer is formed to surround around a region below said base layer in said collector well.

13. The semiconductor device according to claim 10, wherein said heavily doped layer has a second upwardly extending portion extending to the surface of said semiconductor substrate between said first insulating film and said fourth insulating film, and
another collector electrode is provided on the surface of said semiconductor substrate to contact with said second upwardly extending portion.

14. The semiconductor device according to claim 10, further comprising:
a second contact plug extending into the depth direction in said semiconductor substrate between said first insulating film and said fourth insulating film,
wherein said collector electrode is formed in said collector well to contact with said heavily doped layer and said second contact plug.

15. The semiconductor device according to claim 1, wherein said collector well has a carrier density profile in which said carrier density is lower under said base layer, increases to have a peak carrier density in a middle portion of said collector well in the depth direction, and decreases from the peak carrier density into the depth direction from the middle portion.

16. A method of manufacturing a semiconductor device, comprising:
(a) forming an STI (Shallow Trench Isolation) structure with a plurality of insulating films in a surface of a semiconductor substrate;
(b) forming a collector well in said semiconductor substrate in a depth direction to have a first region from a surface of said semiconductor substrate between two of said plurality of insulating films as first and second insulating films and a second region extending from said first region under said plurality of insulating films;
(c) forming a base layer to be in contact with said collector well; and
(d) forming a heavily doped layer under at least one of said plurality of insulating films within said second region of said collector well such that a carrier density of an upper portion of said heavily doped layer is equal to or higher than that of said collector well in a portion corresponding to said upper portion.

17. The method according to claim 16, wherein said (d) forming comprises:
(e) forming a vertical heavily doped layer between said second insulating film and one of said plurality of insulating films as a third insulating film which is provided on a side opposite to said base layer with respect to said second insulating film; and
(f) forming a horizontal heavily doped layer under at least one of said plurality of insulating films within said second region of said collector well such that said horizontal heavily doped layer is connected to said vertical heavily doped layer.

18. The method according to claim 17, wherein said (f) forming is carried out such that said horizontal heavily doped layer extends around a region below said base layer in said collector well.

19. The method according to claim 17, wherein said (f) forming is carried out such that said horizontal heavily doped layer forms a ring shape surrounding a region below said base layer in said collector well.

20. The method according to claim 17, wherein said (f) forming is carried out such that a horizontal distance between said base layer and a base side edge of said horizontal heavily doped layer is equal to or more than 0.1 μm.

21. The method according to claim 16, further comprising:
(g) forming a collector electrode in said collector well below a region between said second insulating film and one of said plurality of insulating films as a third insulating film which is provided on a side opposite to said base layer with respect to said second insulating film; and
(h) forming a contact plug on said collector electrode between said second insulating film and said third insulating film, wherein said heavily doped layer is connected to said collector electrode and horizontally extends to under at least one of said plurality of insulating films.

22. The method according to claim 21, wherein said (d) forming is carried out such that said heavily doped layer extends around a region below said base layer in said collector well.

23. The method according to claim 21, wherein said (d) forming is carried out such that said heavily doped layer forms a ring shape surrounding a region below said base layer in said collector well.

24. The method according to claim 21, wherein said (d) forming is carried out such that a horizontal distance between said base layer and a base side edge of said heavily doped layer is equal to or more than 0.1 μm.
